(19) United States
(12) Patent Application Publication
(10) Pub. No.: US 2021/0285124 A1
(43) Pub. Date: Sep. 16, 2021

(54) METHOD FOR PRODUCING GALLIUM NITRIDE CRYSTAL

(71) Applicant: DEXERIALS CORPORATION, Tokyo (JP)

(72) Inventors: Shinya AKIYAMA, Tokyo (JP); Makoto WATANABE, Tokyo (JP)

(73) Assignee: DEXERIALS CORPORATION, Tokyo (JP)

(21) Appl. No.: 16/328,427

(22) PCT Filed: Sep. 4, 2017
(86) PCT No.: PCT/JP2017/031792

§ 371 Date: Feb. 26, 2019

(30) Foreign Application Priority Data
Sep. 12, 2016 (JP) 2016-177666

(51) Int. Cl. C30B 19/12; C30B 29/40

(52) U.S. Cl. CPC C30B 19/12; C30B 29/406

(57) ABSTRACT

There is provided a method for producing a gallium nitride crystal that can produce a gallium nitride crystal more efficiently, using liquid phase growth, the method for producing a gallium nitride crystal including: a step of adding at least one or more of a nitride of an alkali metal or an alkaline earth metal and a transition metal to metal gallium and iron nitride and performing heating in a nitrogen atmosphere to at least a reaction temperature at which the metal gallium reacts.

### TECHNICAL FIELD

The present invention relates to a method for producing a gallium nitride crystal.

### BACKGROUND ART

These days, gallium nitride (GaN) is drawing attention as a semiconductor material for forming a blue light emitting diode, a semiconductor laser, a high-voltage, high-frequency power source integrated circuit (IC), or the like.

A gallium nitride crystal can be synthesized by, for example, using a vapor phase growth method such as hydride vapor phase epitaxy (HVPE) or metal organic chemical vapor deposition (MOCVD). Specifically, a gallium nitride crystal can be produced by reacting a gas such as ammonia (NH₃) and a gallium (Ga) source on a sapphire substrate or a silicon carbide (SiC) substrate on which a buffer layer is formed as a film, in a temperature region of more than or equal to 1000° C. However, a large number of crystal defects exist in a gallium nitride crystal synthesized by vapor phase growth, and hence it has been difficult to obtain target characteristics when the crystal is incorporated in a device.

Thus, a method in which a gallium nitride crystal is grown in a liquid phase is studied in order to reduce the amount of defects in a crystal. However, to grow a gallium nitride crystal in a liquid phase, it is necessary that nitrogen gas be melted at an ultrahigh pressure of more than or equal to ten thousand atmospheres in a gallium melt that has a high temperature of more than or equal to 1500° C. Hence, the liquid phase growth method that requires reaction equipment resistant to high-temperature and high-pressure conditions has yet to achieve industrial application.

Patent Literature 1 below discloses a method for producing a gallium nitride crystal in which metal sodium is used as flux in order to ease the high-temperature and high-pressure conditions mentioned above, for example. Further, Patent Literature 2 below discloses a method for synthesizing a gallium nitride crystal in which an alkali metal or an alkaline earth metal and tin are used as flux.

### CITATION LIST

### Patent Literature

Patent Literature 1: U.S. Pat. No. 5,868,837B

Patent Literature 2: JP 2014-152066A

### SUMMARY OF INVENTION

### Technical Problem

However, in the method disclosed in Patent Literature 1, it is necessary to react gallium and nitrogen in high-pressure conditions of more than or equal to 50 atmospheres, and hence an expensive reaction apparatus resistant to high-temperature and high-pressure conditions has been required after all. Further, in the method disclosed in Patent Literature 2, it is necessary to use large amounts of an alkali metal or an alkaline earth metal and tin as flux, and the amount of gallium contained in the melt is reduced; consequently, the rate of growth of a gallium nitride crystal has been slow, and productivity has been low.

Thus, the present invention has been made in view of the problem mentioned above, and an object of the present invention is to provide a new and improved method for producing a gallium nitride crystal that can produce a gallium nitride crystal more efficiently, using liquid phase growth.

### Solution to Problem

To solve the problem described above, according to an aspect of the present invention, there is provided a method for producing a gallium nitride crystal including: a step of adding at least one or more of a nitride of an alkali metal or an alkaline earth metal and a transition metal to metal gallium and iron nitride and performing heating in a nitrogen atmosphere to at least a reaction temperature at which the metal gallium reacts.

The nitride of an alkaline earth metal may be added to the metal gallium and the iron nitride.

The nitride of an alkaline earth metal may be magnesium nitride.

The transition metal may be any one of manganese, cobalt, and chromium.

The iron nitride may contain at least one or more of tetrairon mononitride, triiron mononitride, and diiron mononitride.

The reaction temperature may be more than or equal to 550° C. and less than or equal to 1000° C.

The gallium nitride crystal may be formed on a substrate by a liquid phase epitaxy method.

The substrate may be a sapphire substrate.

Gallium nitride crystals may be formed on both surfaces of the substrate simultaneously.

### Advantageous Effects of Invention

As described above, according to the present invention, a high-quality gallium nitride crystal with few crystal defects can be grown at higher speed. Therefore, according to the present invention, a gallium nitride crystal can be produced more efficiently.

### BRIEF DESCRIPTION OF DRAWINGS

FIG. 1 is a schematic diagram showing an example of a reaction apparatus used in a method for producing a gallium nitride crystal according to a first embodiment of the present invention.

FIG. 2 is a schematic diagram showing an example of a reaction apparatus used in a method for producing a gallium nitride crystal according to a second embodiment of the present invention.

FIG. 3 is a perspective view showing a holder for a substrate shown in FIG. 2 more specifically.

FIG. 4 is a cross-sectional view showing a structure of a substrate on which gallium nitride crystal films have been grown in a third embodiment of the present invention.

FIG. 5 is a perspective view showing an example of a holder for synthesizing crystal films of gallium nitride on both surfaces of a substrate in the third embodiment of the present invention.

FIG. 6 is a SEM image in which a gallium nitride crystal produced in Example 1 is observed with a magnification of 15,000 times.

FIG. 7 is a SEM image in which a gallium nitride crystal produced in Example 2 is observed with a magnification of 30,000 times.

FIG. 8 is a SEM image in which a gallium nitride crystal produced in Comparative Example 1 is observed with a magnification of 30,000 times.

FIG. 9 is a SEM image in which a gallium nitride crystal produced in Comparative Example 2 is observed with a magnification of 100 times.

FIG. 10 is a graph showing a temperature profile at a time of heating of Example 3.

FIG. 11 is a graph showing an XRD spectrum of a gallium nitride crystal film precipitated on a sapphire substrate in Example 3.

FIG. 12 is a graph showing a temperature profile at a time of heating of Comparative Example 3.

FIG. 13 is a graph showing an XRD spectrum of a gallium nitride crystal film precipitated on a sapphire substrate in Example 4.

FIG. 14 is a surface form profile obtained by measuring warpage of a sapphire substrate according to Example 4.

FIG. 15 is a surface form profile obtained by measuring warpage of a sapphire substrate according to Comparative Example 4.

### DESCRIPTION OF EMBODIMENTS

Hereinafter, (a) preferred embodiment(s) of the present invention will be described in detail with reference to the appended drawings. Note that, in this specification and the appended drawings, structural elements that have substantially the same function and structure are denoted with the same reference numerals, and repeated explanation of these structural elements is omitted.

### 1. First Embodiment

(Reaction Apparatus)

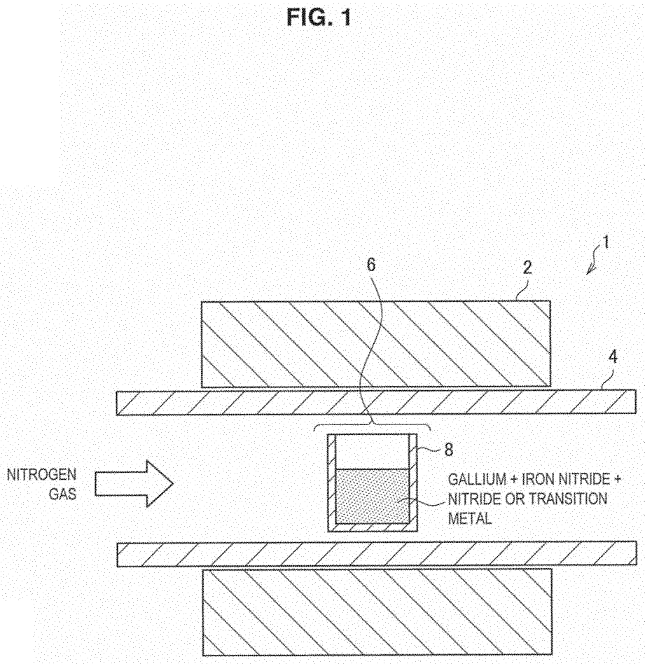

First, a method for producing a gallium nitride crystal according to a first embodiment of the present invention is described with reference to FIG. 1. FIG. 1 is a schematic diagram showing an example of a reaction apparatus 1 used in a method for producing a gallium nitride crystal according to the present embodiment.

As shown in FIG. 1, the reaction apparatus 1 used in the method for producing a gallium nitride crystal according to the present embodiment is a reaction apparatus that includes a tubular furnace 4 in the interior of an electric furnace 2 and in which a central portion in the longitudinal direction of the tubular furnace 4 is set as a burning zone 6.

A reaction vessel 8 having high heat resistance is housed in the burning zone 6 of the interior of the tubular furnace 4. The reaction vessel 8 is formed of, for example, carbon in order to prevent an impurity such as oxygen from being mixed in reaction materials. However, the reaction vessel 8 may be formed of a material other than carbon as long as it is a substance that does not react with metal gallium at high temperatures around 1000° C.; for example, may be formed of aluminum oxide.

Reaction materials serving as source materials of a gallium nitride crystal are put into the reaction vessel 8, and are heated by the electric furnace 2; thereby, the synthesis reaction of a gallium nitride crystal progresses. Specifically, metal gallium and iron nitride and at least one or more of a nitride of an alkali metal or an alkaline earth metal and a transition metal are put into the reaction vessel 8, and are heated until they enter a molten state; thereby, the synthesize reaction of a gallium nitride crystal progresses.

A gas supply means (not illustrated) that supplies nitrogen gas, which is an atmosphere gas, to the interior of the tubular furnace 4 is connected to the tubular furnace 4. The method for producing a gallium nitride crystal according to the present embodiment can synthesize a gallium nitride crystal under normal pressure, and hence the reaction apparatus 1 may not have a special pressure-resistant structure. Thus, in the method for producing a gallium nitride crystal according to the present embodiment, the reaction apparatus 1 is easy to increase in size, and can therefore be industrialized easily.

In the present embodiment, a reaction apparatus 1 like that shown in FIG. 1 is used, and metal gallium, iron nitride, and a nitride of an alkali metal or an alkaline earth metal or a transition metal, which are reaction materials, are heated in a reaction vessel and are brought into a molten state. Thereby, in the present embodiment, a gallium nitride crystal can be synthesized by reacting together metal gallium in the melt and nitrogen atoms in the melt or nitrogen molecules of the atmosphere gas.

(Reaction Material)

As the metal gallium, high-purity metal gallium is preferably used, and commercially available metal gallium with a purity of more than or equal to approximately 99.99% may be used, for example.

As the iron nitride, specifically, tetrairon mononitride (Fe₄N), triiron mononitride (Fe₃N), or diiron mononitride (Fe₂N), or a mixture of two or more of these may be used. As the iron nitride, high-purity iron nitride is preferably used, and commercially available iron nitride with a purity of more than or equal to approximately 99.9% may be used.

Iron atoms in the iron nitride function as a catalyst by being mixed with metal gallium and heated, and produce active nitrogen from nitrogen atoms in the melt or nitrogen molecules in the atmosphere gas. The produced active nitrogen reacts with metal gallium easily; thus, the synthesis of a gallium nitride crystal can be promoted. Thereby, in the method for producing a gallium nitride crystal according to the present embodiment, a gallium nitride crystal can be synthesized by liquid phase growth at normal pressure, which is lower than in a conventional flux method. That is, since iron nitride functions as a catalyst, the concentration of iron nitride in the reaction materials is not particularly limited, and it is sufficient for iron nitride to be contained at least in the reaction materials.

Specifically, in the case where tetrairon mononitride is used as the iron nitride, the iron nitride reacts with metal gallium by the nitriding action of tetrairon mononitride, and produces a gallium nitride crystal (Reaction Formula 1).

Fe₄N+13Ga->GaN+4FeGa₃ Reaction Formula 1

A nitrogen molecule that is dissolved in the melt from the nitrogen atmosphere reacts with metal gallium by an iron atom functioning as a catalyst, and produces a gallium nitride crystal (Reaction Formula 2).

2Ga+N₂+Fe->2GaN+Fe Reaction Formula 2

The mixing ratio between metal gallium and iron nitride may be, for example, a ratio whereby the proportion of the mole number of the iron element in the iron nitride to the total mole number of metal gallium and the iron element of the iron nitride is more than or equal to 0.1% and less than or equal to 50%. If the proportion of the iron element is less than 0.1%, the amount of the iron element, which is a catalyst, is small, and the rate of growth of the gallium nitride crystal is slow. If the proportion of the iron element is more than 50%, not only gallium nitride but also gallium oxide or the like is produced, and the growth of the gallium nitride crystal may be inhibited.

For example, in the case where tetrairon mononitride is used as the iron nitride, the ratio between the mole numbers of metal gallium and tetrairon mononitride may be set to approximately 99.97:0.03 to 80:20 in order to satisfy the proportion of the mole number of the iron element in the iron nitride mentioned above.

In the case where triiron mononitride or diiron mononitride is used as the iron nitride, the ratio of the mole number described above may be converted in accordance with the proportion between the iron element and the nitrogen element in the iron nitride. For example, in the case where triiron mononitride is used as the iron nitride, the ratio between the mole numbers of metal gallium and triiron mononitride may be set to approximately 99.96:0.04 to 75:25. In the case where diiron mononitride is used as the iron nitride, the ratio between the mole numbers of metal gallium and diiron mononitride may be set to approximately 99.94:0.06 to 67.5:32.5.

As the nitride of an alkali metal or an alkaline earth metal, specifically, lithium nitride (Li₃N), sodium nitride (Na₃N), magnesium nitride (Mg₃N₂), or calcium nitride (Ca₃N₂), or a mixture of two or more of these may be used. Further, as the nitride of an alkali metal or an alkaline earth metal, one with a high purity is preferably used, and a commercially available one with a purity of more than or equal to approximately 99.9% may be used.

The nitride of an alkali metal or an alkaline earth metal functions as a quasi-nitrogen source. Further, the nitride of an alkali metal or an alkaline earth metal supplies nitrogen atoms into the melt efficiently by alkali metal atoms or alkaline earth metal atoms reacting with nitrogen molecules in the atmosphere gas. Thereby, in the method for producing a gallium nitride crystal according to the present embodiment, the concentration of nitrogen in the melt can be raised, and accordingly the rate of growth of a gallium nitride crystal can be improved.

Hence, in the method for producing a gallium nitride crystal according to the present embodiment, it is preferable to use a nitride of an alkali metal or an alkaline earth metal, which has high reactivity with nitrogen molecules.

Specifically, it is preferable to use a nitride of an alkaline earth metal, and it is more preferable to use magnesium nitride (Mg₃N₂).

The addition amount of the nitride of an alkali metal or an alkaline earth metal is not particularly limited; for example, may be more than or equal to 0.01 mass % and less than or equal to 50 mass % relative to the total mass of metal gallium and iron nitride. If the addition amount of the nitride of an alkali metal or an alkaline earth metal is less than 0.1 mass %, the effect of causing the growth of a gallium nitride crystal to be promoted is not obtained. Further, if the addition amount of the nitride of an alkali metal or an alkaline earth metal is more than 50 mass %, the ratio of metal gallium is reduced, and consequently the efficiency of synthesis of a gallium nitride crystal is lowered.

In the method for producing a gallium nitride crystal according to the present embodiment, a transition metal nitride such as titanium nitride, or a nitrogen compound such as calcium cyanamide may be added in place of the nitride of an alkali metal or an alkaline earth metal described above or in combination with the nitride of an alkali metal or an alkaline earth metal described above.

The transition metal functions as a catalyst, and promotes reaction between gallium and nitrogen. As the transition metal, specifically, a simple substance of at least any one metal of manganese (Mn), cobalt (Co), and chromium (Cr) may be used. As the transition metal, one with a high purity is preferably used, and a commercially available one with a purity of more than or equal to approximately 99.9% may be used.

The addition amount of the transition metal is not particularly limited; for example, may be more than or equal to 0.01 mass % and less than or equal to 50 mass % relative to the total mass of metal gallium and iron nitride. If the addition amount of the transition metal is less than 0.1 mass %, the effect of causing reaction to be promoted is not obtained. Further, if the addition amount of the transition metal is more than 50 mass %, the ratio of metal gallium is reduced, and consequently the efficiency of synthesis of a gallium nitride crystal is lowered.

In the method for producing a gallium nitride crystal according to the present embodiment, either one of a nitride of an alkali metal or an alkaline earth metal and a transition metal may be added to metal gallium and iron nitride, or both may be added.

The atmosphere gas supplied to the interior of the tubular furnace 4 may be nitrogen gas, for example. However, another gas may be used as long as it does not form an impurity such as an oxide with metal gallium. For example, as the atmosphere gas, inert gases such as argon gas may be used, and a plurality of gases among the gases mentioned above may be used in mixture.

(Heating Conditions)

In the method for producing a gallium nitride crystal according to the present embodiment, reaction materials put in the reaction vessel 8 are heated to at least a reaction temperature at which metal gallium reacts. Thereby, the reaction materials put in the reaction vessel 8 enter a molten state, and metal gallium and nitrogen atoms in the melt or nitrogen molecules in the atmosphere gas react together; thus, a gallium nitride crystal is synthesized. Such a reaction temperature is specifically more than or equal to 300° C. and less than or equal to 1000° C., and is preferably more than or equal to 550° C. and less than or equal to 1000° C.

After the reaction materials put in the reaction vessel 8 have reached the reaction temperature, the reaction materials are held at a temperature within the range of reaction temperature mentioned above for a prescribed time. The time during which the reaction materials are held within the range of reaction temperature mentioned above may be more than or equal to one hour, for example. At this time, the temperature of the reaction materials may be constant or may vary as long as it is within the range of reaction temperature mentioned above (for example, more than or equal to 300° C. and less than or equal to 1000° C., preferably more than or equal to 550° C. and less than or equal to 1000° C.).

In the method for producing a gallium nitride crystal according to the present embodiment, a gallium nitride crystal is synthesized at less than or equal to 1000° C., and thus a gallium nitride crystal that is once synthesized is not decomposed. Therefore, in the method for producing a gallium nitride crystal according to the present embodiment, a gallium nitride crystal can be produced with higher efficiency.

There is a case where a by-product such as an intermetallic compound of iron and gallium is contained in a product obtained by the reaction mentioned above. Such a by-product can be removed by, for example, acid washing using an acid such as aqua regia.

By the above method, a gallium nitride crystal can be produced more efficiently by liquid phase growth in a nitrogen atmosphere of normal pressure.

### 2. Second Embodiment

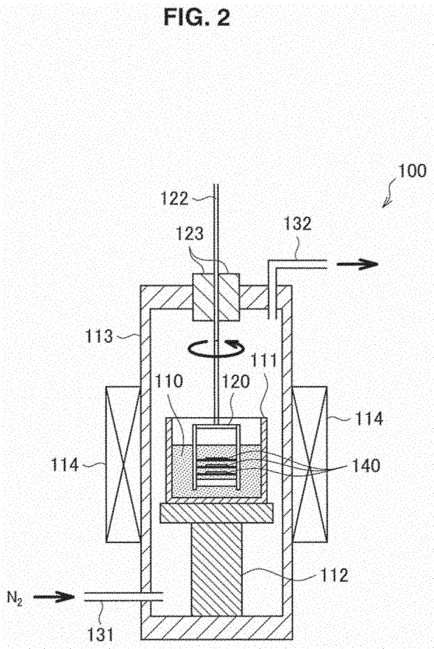

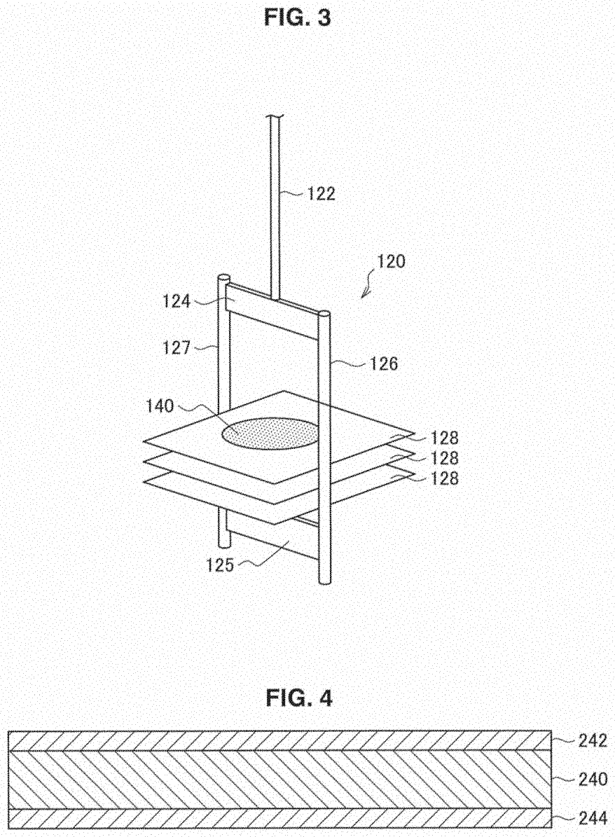

Next, a method for producing a gallium nitride crystal according to a second embodiment of the present invention is described with reference to FIG. 2 and FIG. 3.

The method for producing a gallium nitride crystal according to the second embodiment of the present invention is a method in which a substrate serving as a nucleus of crystal growth is immersed in a melt obtained by melting metal gallium and iron nitride and at least one or more of a nitride of an alkali metal or an alkaline earth metal and a transition metal, and thereby a gallium nitride crystal film is epitaxially grown on the substrate. That is, the present embodiment is a method for producing a gallium nitride crystal using a liquid phase epitaxy method in which the crystal growth orientation of a synthesized gallium nitride crystal film can be made to coincide with the crystal orientation of a substrate. By the method for producing a gallium nitride crystal according to the present embodiment, a gallium nitride crystal with a uniform crystal orientation suitable for the production of a semiconductor element can be produced.

The production method according to the second embodiment differs from the production method according to the first embodiment only in the reaction apparatus used; and the reaction materials used and the heating conditions are substantially similar, and hence a description herein is omitted.

FIG. 2 is a schematic diagram showing an example of a reaction apparatus 100 used in a method for producing a gallium nitride crystal according to the present embodiment.

As shown in FIG. 2, the reaction apparatus 100 includes an electric furnace 113, a heater 114 provided on the side surface of the electric furnace 113, a gas introduction port 131, a gas exhaust port 132, a lifting shaft 122, and a sealing material 123 that ensures airtightness between the lifting shaft 122 and the electric furnace 113. A base 112 on which a reaction vessel 111 in which a melt 10 of reaction materials is put is mounted is provided in the interior of the electric furnace 113, and a holder 120 that holds a substrate 140 serving as a nucleus of a gallium nitride crystal is provided at one end of the lifting shaft 122. That is, the reaction apparatus 100 is an apparatus that epitaxially grows a crystal film of gallium nitride on the substrate 140 that is immersed in a melt 110 obtained by melting reaction materials.

The electric furnace 113 houses the reaction vessel 111 in a sealed-up inner structure. For example, the electric furnace 113 may be a cylindrical structure in which the diameter of the interior is approximately 200 mm and the height of the interior is approximately 800 mm. The heater 114 is placed on the side surface in the longitudinal direction of the electric furnace 113, and heats the interior of the electric furnace 113, for example.

The gas introduction port 131 is provided in a lower portion of the electric furnace 113, and introduces an atmosphere gas (for example, nitrogen (N₂) gas) into the electric furnace 113. The gas exhaust port 132 is provided in an upper portion of the electric furnace 113, and exhausts the atmosphere gas in the interior of the electric furnace 113. By the gas introduction port 131 and the gas exhaust port 132, the pressure of the interior of the electric furnace 113 is kept to be approximately normal pressure (that is, atmospheric pressure).

The base 112 is a member that supports the reaction vessel 111. Specifically, the base 112 supports the reaction vessel 111 in such a manner that the reaction vessel 111 is equally heated by the heater 114. For example, the height of the base 112 may be a height whereby the reaction vessel 111 is located on a central portion of the heater 114.

The reaction vessel 111 is a vessel that holds a melt 110 obtained by melting reaction materials. The reaction vessel 111 may be a vessel of a circular cylindrical shape with an outer diameter (diameter) of approximately 100 mm, a height of approximately 90 mm, and a thickness of approximately 5 mm, for example. The reaction vessel 111 is formed of, for example, carbon, but may be formed of another material such as aluminum oxide as long as it is a material that does not react with metal gallium at high temperatures around 1000° C.

The melt 110 is a liquid obtained by melting reaction materials. Specifically, the melt 110 is a liquid obtained by heating and melting a mixed powder of metal gallium, iron nitride, and at least one or more of a nitride of an alkali metal or an alkaline earth metal and a transition metal, which are reaction materials, with the heater 114.

The substrate 140 is a substrate on a surface of which a crystal film of gallium nitride can be precipitated. The substrate 140 may be specifically a sapphire substrate. The shape of the substrate 140 may be any shape; for example, may be a substantially flat plate-like shape, a substantially circular plate-like shape, or the like. For example, a sapphire substrate cut out with the crystal plane of (0 0 2) may be used as the substrate 140, and thereby a crystal film of gallium nitride that has grown by crystal growth with an orientation coinciding with the crystal orientation of the substrate 140 and that is orientated in the c-axis direction can be synthesized.

The sealing material 123 is provided between the lifting shaft 122 and the electric furnace 113, and maintains airtightness in the electric furnace 113. The sealing material 123 prevents the air outside the electric furnace 113 from flowing into the interior of the electric furnace 113, and thereby the atmosphere of the interior of the electric furnace 113 can be made to be an atmosphere of gas introduced from the gas introduction port 131 (for example, a nitrogen atmosphere).

The lifting shaft 122 immerses the substrate 140 in the melt 110, and lifts the substrate 140 from the melt 110. Specifically, the lifting shaft 122 is provided to pierce the upper surface of the electric furnace 113, and the holder 120 that holds the substrate 140 is provided at one end of the lifting shaft 122 in the interior of the electric furnace 113. Therefore, the substrate 140 held by the holder 120 can be immersed in the melt 110 and be lifted by raising and lowering the lifting shaft 122.

The lifting shaft 122 may be provided to be rotatable about the shaft. In such a case, by rotating the lifting shaft 122, the substrate 140 held by the holder 120 can be rotated, and the melt 110 can be stirred. By rotating and stirring the melt 110, the nitrogen concentration distribution in the melt 110 can be made more uniform, and accordingly a crystal film of gallium nitride can be synthesized more uniformly.

The holder 120 holds a plate-like substrate 140 horizontally. The holder 120 allows a crystal film of gallium nitride to grow uniformly by holding the substrate 140 horizontally so as to reduce the influence of the nitrogen concentration distribution in the depth direction of the melt 110. The holder 120 may be formed of carbon similarly to the reaction vessel 111, but may be formed of another material such as aluminum oxide as long as it is a material that does not react with metal gallium even at high temperature around 1000° C.

Here, a more specific shape of the holder 120 is described with reference to FIG. 3. FIG. 3 is a perspective view showing the holder 120 for the substrate 140 shown in FIG. 2 more specifically.

As shown in FIG. 3, the holder 120 has a structure in which both ends of prop portions 126 and 127 that are two columnar members are linked together by beam portions 124 and 125. At least one or more shelf boards 128 are provided in the space formed by the prop portions 126 and 127 and the beam portions 124 and 125. The shelf board 128 can hold the substrate 140 horizontally by being provided perpendicularly to the prop portions 126 and 127.

The holder 120 may include a plurality of shelf boards 128. In such a case, the holder 120 allows crystal films of gallium nitride to be synthesized on a plurality of substrates 140 by simultaneously immersing the plurality of substrates 140 in the melt 110 in the reaction vessel 111. The spacing between shelf boards 128 may be approximately 10 mm, for example.

By the above configuration, the reaction apparatus 100 can synthesize a crystal film of gallium nitride with a crystal orientation coinciding with the crystal orientation of the substrate 140 (that is, epitaxially grown).

### 3. Third Embodiment

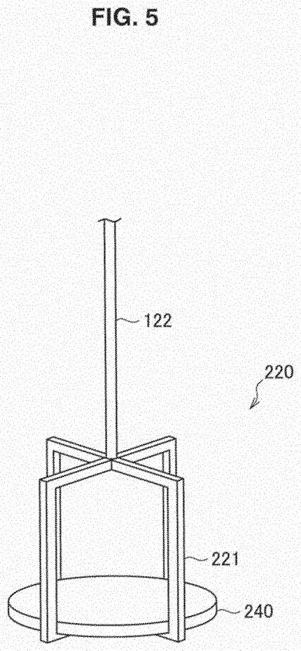

Next, a method for producing a gallium nitride crystal according to a third embodiment of the present invention is described with reference to FIG. 4 and FIG. 5.

The method for producing a gallium nitride crystal according to the third embodiment of the present invention synthesizes crystal films of gallium nitride on both surfaces of a substrate serving as a nucleus of crystal growth, and thereby prevents the warpage of the substrate that would occur due to a difference in thermal expansion coefficient between the substrate and the gallium nitride crystal.

As described above, in the methods for producing a gallium nitride crystal according to the first and second embodiments of the present invention, a gallium nitride crystal is synthesized by heating reaction materials to the temperature range of more than or equal to 300° C. and less than or equal to 1000° C. Hence, after the synthesis of a crystal, when the substrate is cooled to approximately room temperature, the substrate warps on the gallium nitride crystal side, because the magnitude of thermal shrinkage is different between the substrate and the gallium nitride crystal. When forming a fine semiconductor element by using the synthesized gallium nitride crystal, such deformation of the substrate can be a cause of reduction in processing accuracy.

In the method for producing a gallium nitride crystal according to the third embodiment of the present invention, crystal films of gallium nitride are synthesized on both surfaces of a substrate simultaneously, and thereby an event in which, when the substrate is cooled, the substrate warps on the side of one surface can be prevented.

The production method according to the third embodiment differs from the production methods according to the first and second embodiments only in the substrate and the holder used; and the reaction materials used and the heating conditions are substantially similar, and hence a description herein is omitted.

First, a substrate 240 in the method for producing a gallium nitride crystal according to the present embodiment is described with reference to FIG. 4. FIG. 4 is a cross-sectional view showing the structure of a substrate 240 on which gallium nitride crystal films have been grown in the present embodiment.

As shown in FIG. 4, in the method for producing a gallium nitride crystal according to the present embodiment, gallium nitride crystal films 242 and 244 are synthesized on both surfaces of a substrate 240 of a substantially flat plate-like shape or a substantially circular plate-like shape. Both surfaces of the substrate 240 on which the gallium nitride crystal films 242 and 244 have been precipitated had been mirror-polished. For example, a sapphire substrate that is cut out with the crystal plane of (0 0 2) and of which both surfaces are mirror-polished may be used as the substrate 240, and both surfaces of the substrate 240 may be brought into contact with a melt obtained by melting reaction materials; thereby, gallium nitride crystals can be precipitated on both surfaces of the substrate 240.

Here, in order to allow both surfaces of the substrate 240 to come into contact with a melt obtained by melting reaction materials, a holder 220 like that shown in FIG. 5 may be used in place of the holder 120 shown in FIG. 3. FIG. 5 is a perspective view showing an example of the holder 220 for synthesizing gallium nitride crystal films on both surfaces of the substrate 240 in the present embodiment.

As shown in FIG. 5, the holder 220 includes a plurality of hook portions 221 at the tip of the lifting shaft 122, and catches parts of the substrate 240 with the plurality of hook portions 221 to hold the substrate 240. Thereby, both surfaces of the substrate 240 can be exposed and be brought into contact with the melt 110, and thus gallium nitride crystal films can be precipitated on both surfaces of the substrate 240.

On the other hand, in a holder 120 like that shown in FIG. 3, the substrate 140 is mounted on the shelf board 128, and hence the surface in contact with the shelf board 128 of the substrate 140 is not exposed. Therefore, the melt 110 does not come into contact with the surface in contact with the shelf board 128 of the substrate 140, and a gallium nitride crystal film is not precipitated on the surface.

Thus, in the method for producing a gallium nitride crystal according to the present embodiment, the warpage of the substrate 240 can be prevented by synthesizing gallium nitride crystal films by using a substrate 240 of which both surfaces are mirror-polished and using the holder 220 capable of exposing both surfaces of the substrate 240. According to the present embodiment, deformation such as warpage can be prevented on a substrate on which a gallium nitride crystal film has been synthesized, and thus dimensional accuracy can be improved when using the gallium nitride crystal film to form a semiconductor element. Furthermore, since gallium nitride crystal films can be precipitated on both surfaces of a substrate simultaneously, gallium nitride crystals can be produced more efficiently.

### EXAMPLES

In the following, the method for producing a gallium nitride crystal according to each embodiment of the present invention is described more specifically with reference to Examples. Examples shown below are condition examples for describing the feasibility and effect of the method for producing a gallium nitride crystal according to each embodiment of the present invention, and the present invention is not limited to Examples below.

The metal gallium (purity: 99.99999%) used in Test Examples 1 to 3 below was purchased from Dowa Electronics Materials CO., LTD. Further, the tetrairon mononitride (Fe₄N, purity: 99.9%), the magnesium nitride (Mg₃N₂, purity: 99.9%), and the lithium nitride (Li₃N, purity: 99.9%) were purchased from Kojundo Chemical Co., Ltd. Further, the nitrogen gas (purity: 99.99%) was purchased from Taiyo Nippon Sanso Corporation.

### Test Example 1

First, Test Example 1 corresponding to the method for producing a gallium nitride crystal according to the first embodiment is described.

### Example 1

First, a reaction material in which powders of metal gallium (Ga), tetrairon mononitride (Fe₄N), and magnesium nitride (Mg₃N₂) were mixed together at a ratio of Ga:Fe₄N:Mg₃N₂=96 mol %:2 mol %:2 mol % was put into a reaction vessel placed in the interior of the reaction apparatus shown in FIG. 1.

Next, nitrogen gas was introduced into the interior of the reaction apparatus at a flow rate of approximately 3000 mL per minute, and the interior of the reaction apparatus was set to 1 atmosphere of substantially 100% nitrogen and was then held at 900° C. for 10 hours; thereby, a gallium nitride crystal was synthesized. After that, the interior of the reaction apparatus was naturally cooled to room temperature by spending 10 hours, and by-products were removed with aqua regia; thus, the gallium nitride crystal was isolated.

### Example 2

A gallium nitride crystal was synthesized by a similar method to Example 1 except that a gallium nitride crystal was synthesized by using, as a reaction material, a material in which powders of metal gallium (Ga), tetrairon mononitride (Fe₄N), and lithium nitride (Li₃N) were mixed together at a ratio of Ga:Fe₄N:Li₃N=94 mol %:3 mol %:3 mol % and holding the state at 850° C. for 10 hours.

### Comparative Example 1

A gallium nitride crystal was synthesized by a similar method to Example 1 except that a material in which powders of metal gallium (Ga) and tetrairon mononitride (Fe₄N) were mixed together at a ratio of Ga:Fe₄N=98 mol %:2 mol % was used as a reaction material.

### Comparative Example 2

A gallium nitride crystal was synthesized by a similar method to Example 1 except that a material in which powders of metal gallium (Ga) and magnesium nitride (Mg₃N₂) were mixed together at a ratio of Ga:Mg₃N₂=97 mol %:3 mol % was used as a reaction material.

(Evaluation)

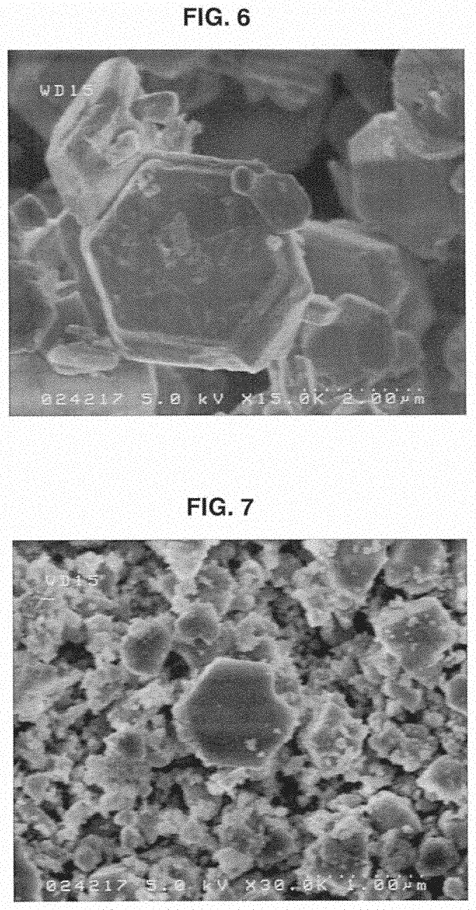

The gallium nitride crystals synthesized in Examples 1 and 2 and Comparative Examples 1 and 2 were observed with a scanning electron microscope (SEM) (Hitachi High-Technologies Corporation, S-4500), and SEM images were acquired. The results are shown in FIG. 6 to FIG. 9.

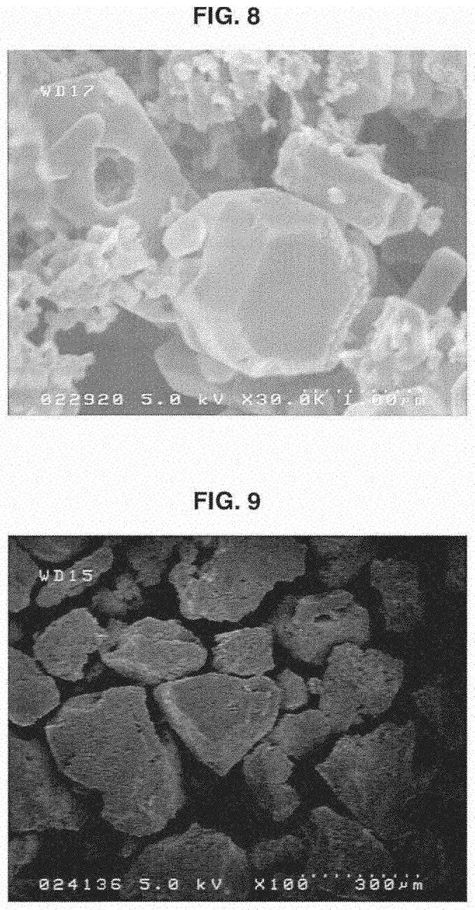

FIG. 6 is a SEM image in which the gallium nitride crystal produced in Example 1 is observed with a magnification of 15,000 times, and FIG. 7 is a SEM image in which the gallium nitride crystal produced in Example 2 is observed with a magnification of 30,000 times. Further, FIG. 8 is a SEM image in which the gallium nitride crystal produced in Comparative Example 1 is observed with a magnification of 30,000 times, and FIG. 9 is a SEM image in which the gallium nitride crystal produced in Comparative Example 2 is observed with a magnification of 100 times.

As can be seen from the SEM images shown in FIG. 6 and FIG. 7, crystals each having a hexagonal columnar or hexagonal plate-like shape have been obtained in Examples 1 and 2. Since gallium nitride has a crystal structure of a hexagonal crystal, it is assessed that these crystals of shapes derived from a crystal structure of a hexagonal crystal are gallium nitride crystals. That is, it can be seen that a gallium nitride crystal can be produced by using the production method according to the present embodiment.

Further, when the SEM images shown in FIG. 6 and FIG. 8 are compared, it can be seen that, by adding a nitride of an alkali metal or an alkaline earth metal to metal gallium and iron nitride, the size of the gallium nitride crystal is increased approximately twice and crystal growth is promoted.

Further, when the SEM images shown in FIG. 6 and FIG. 9 are compared, it can be seen that, in Comparative Example 2 in which iron nitride is not used and only metal gallium and a nitride of an alkali metal or an alkaline earth metal are used, a hexagonal columnar or hexagonal plate-like gallium nitride crystal has not been obtained and a stable gallium nitride crystal is not obtained. Note that the fact that gallium nitride has been synthesized also in Comparative Example 2 has already been checked by X-ray diffraction (XRD) analysis.

Therefore, it can be seen that, in the method for producing a gallium nitride crystal according to the present invention, the growth of a gallium nitride crystal can be promoted by synergy by using metal gallium and iron nitride and at least one or more of a nitride of an alkali metal or an alkaline earth metal and a transition metal in combination.

### Test Example 2

Next, Test Example 2 corresponding to the method for producing a gallium nitride crystal according to the second embodiment is described.

### Example 3

First, a reaction material in which powders of metal gallium (Ga), tetrairon mononitride (Fe₄N), and magnesium nitride (Mg₃N₂) were mixed together at a ratio of Ga:Fe₄N:Mg₃N₂=97.8 mol %:0.2 mol %:2 mol % was put into a reaction vessel placed in the interior of the reaction apparatus shown in FIG. 2. Further, a sapphire substrate having a (0 0 2) plane of a circular plate-like shape with a diameter of 50 mm (Kyocera Corporation) was mounted on each of a plurality of shelf boards of the holder shown in FIG. 3.

Next, nitrogen gas was introduced into the interior of the reaction apparatus at a flow rate of approximately 3000 mL per minute, and the interior of the reaction apparatus was set to 1 atmosphere of substantially 100% nitrogen; then, the sapphire substrates held by the holder were immersed in a melt of the reaction material after melting; thus, a crystal film of gallium nitride was precipitated on each of the sapphire substrates.

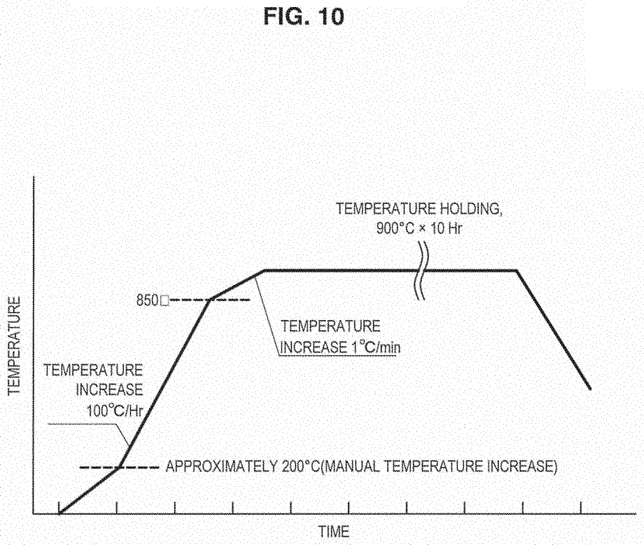

The temperature of the interior of the reaction apparatus was controlled in accordance with the temperature profile shown in FIG. 10. FIG. 10 is a graph showing a temperature profile at the time of heating of Example 3. Specifically, as shown in FIG. 10, first, the temperature of the interior of the reaction vessel was increased to 200° C. manually, and was then raised to approximately 850° C. at a rate of 100° C. per hour. Next, the temperature was gently increased to approximately 900° C. at a rate of 1° C. per minute, and was then held at 900° C. for 10 hours. At this time, the holder was rotated at a rate of 10 rotations per minute about the lifting shaft as the axis, and thereby the melt was stirred. After that, natural cooling was performed by natural heat dissipation until the interior of the reaction vessel returned to room temperature.

### Comparative Example 3

Crystal films of gallium nitride were precipitated on sapphire substrates by a similar method to Example 3 except that a material in which powders of metal gallium (Ga) and tetrairon mononitride (Fe₄N) were mixed together at a ratio of Ga:Fe₄N=99.8 mol %:0.2 mol % was used as a reaction material.

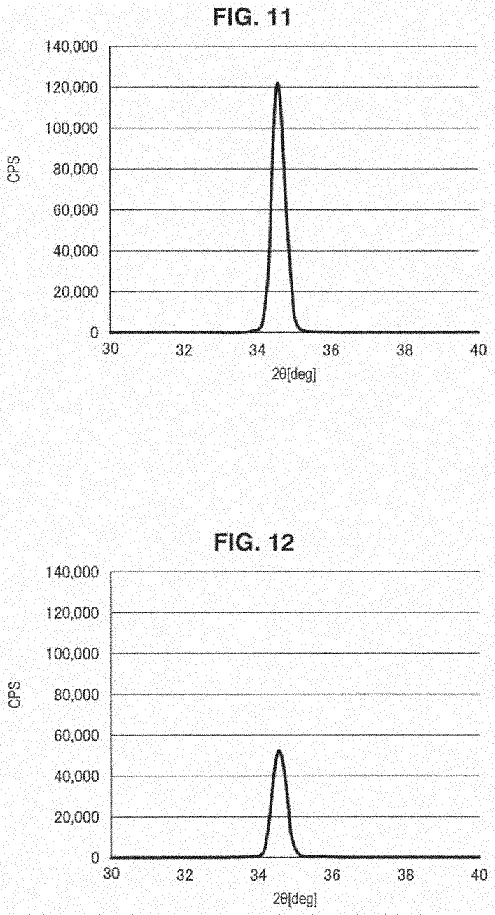

(Evaluation) The sapphire substrate on which a gallium nitride crystal film was precipitated in each of Example 3 and Comparative Example 3 was subjected to X-ray diffraction analysis (XRD) using an X-ray diffraction apparatus (Rigaku Corporation, RINT2500), and XRD spectra were acquired. The results are shown in FIG. 11 and FIG. 12. FIG. 11 is a graph showing an XRD spectrum of the gallium nitride crystal film precipitated on the sapphire substrate in Example 3, and FIG. 12 is a graph showing an XRD spectrum of the gallium nitride crystal film precipitated on the sapphire substrate in Comparative Example 3.

It can be seen that a characteristic peak at 20=34.5° derived from the (0 0 2) plane of gallium nitride is observed in the XRD spectrum shown in each of FIG. 11 and FIG. 12 and that an epitaxially grown gallium nitride crystal has been obtained in each of Example 3 and Comparative Example 3. However, a stronger characteristic peak is observed in the XRD spectrum shown in FIG. 11; thus, it can be seen that a gallium nitride crystal film that has a crystal growth orientation more coinciding with the crystal orientation of the substrate and that is oriented in the c-axis direction can be produced in Example 3 in which a nitride of an alkali metal or an alkaline earth metal was added.

Therefore, it can be seen that, in the method for producing a gallium nitride crystal according to the present embodiment, crystal growth can be promoted and a gallium crystal film with a lower level of defects can be produced by adding at least one or more of a nitride of an alkali metal or an alkaline earth metal and a transition metal.

### Test Example 3

Next, Test Example 3 corresponding to the method for producing a gallium nitride crystal according to the third embodiment is described.

### Example 4

First, a reaction material in which powders of metal gallium (Ga), triiron mononitride (Fe₃N), and magnesium nitride (Mg₃N₂) were mixed together at a ratio of Ga:Fe₃N:Mg₃N₂=97.9 mol %:0.1 mol %:2 mol % was put into a reaction vessel placed in the interior of the reaction apparatus shown in FIG. 2. Further, a sapphire substrate having a (0 0 2) plane of a circular plate-like shape with a diameter of 2 inches (5.08 cm) and a thickness of 0.4 mm (Kyocera Corporation) was caused to be held by the holder shown in FIG. 5. A sapphire substrate of which both surfaces were mirror-polished was used as the sapphire substrate.

Next, nitrogen gas was introduced into the interior of the reaction apparatus at a flow rate of approximately 3000 mL per minute, and the interior of the reaction apparatus was set to 1 atmosphere of substantially 100% nitrogen; then, the sapphire substrate held by the holder was immersed in a melt of the reaction material after melting and was held at 900° C. for 48 hours; thus, gallium nitride crystal films were precipitated on both surfaces of the sapphire substrate. After that, the interior of the reaction vessel was returned to room temperature by natural heat dissipation, then the sapphire substrate was taken out, and the attached reaction material was removed by acid washing.

### Comparative Example 4

A template substrate in which a gallium nitride crystal film was precipitated only on one surface of a sapphire substrate with a diameter of 2 inches by a vapor phase growth method was purchased from Ostendo Technologies, Inc. The film thickness of the gallium nitride crystal film precipitated on the sapphire substrate according to Comparative Example 4 was set to the same as the film thickness of one of the gallium nitride crystal films precipitated on the sapphire substrate according to Example 4.

(Evaluation)

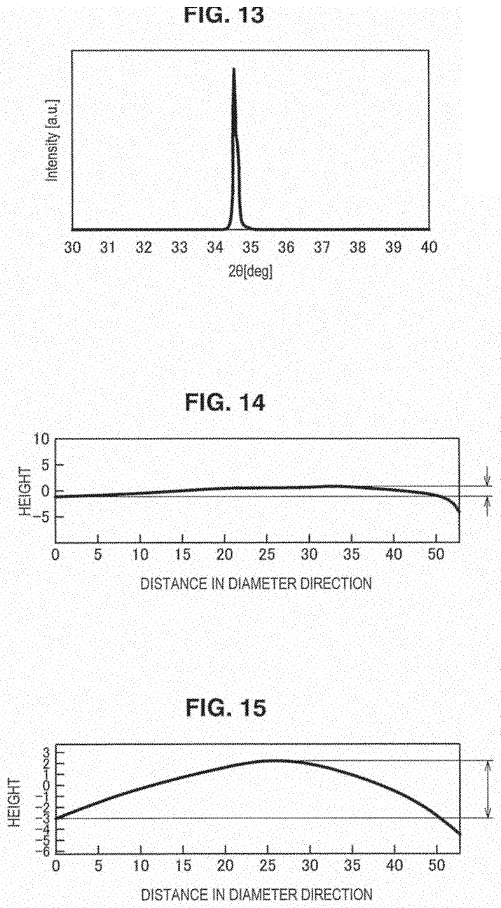

The sapphire substrate on which gallium nitride crystal films were precipitated in Example 4 was subjected to, like in Test Example 2, X-ray diffraction analysis using an X-ray diffraction apparatus, and an XRD spectrum was acquired. The result is shown in FIG. 13. FIG. 13 is a graph showing an XRD spectrum of a gallium nitride crystal film precipitated on the sapphire substrate in Example 4.

As can be seen from the XRD spectrum shown in FIG. 13, it is found that, in Example 4, a characteristic peak at 20=34.5° derived from the (0 0 2) plane of gallium nitride is observed, and an epitaxially grown gallium nitride crystal has been obtained.

Further, the warpage of the sapphire substrate on which a gallium nitride crystal film was precipitated in each of Example 4 and Comparative Example 4 was measured by a non-contact precision outer diameter measuring apparatus (Form Talysurf PGI1250A, produced by Ametek, Inc., Taylor Hobson), and surface form profiles were acquired. The results are shown in FIG. 14 and FIG. 15. FIG. 14 is a surface form profile obtained by measuring the warpage of the sapphire substrate according to Example 4, and FIG. 15 is a surface form profile obtained by measuring the warpage of the sapphire substrate according to Comparative Example 4.

As can be seen from the surface form profiles shown in FIG. 14 and FIG. 15, it is found that, in the sapphire substrate according to Example 4, the maximum value of the amount of change (μm) in the height from one end (0 mm) to another end (50 mm) of the substrate with a diameter of 2 inches (50.8 mm) is less than or equal to approximately 2 μm. On the other hand, it is found that, in the sapphire substrate according to Comparative Example 4, a warpage of approximately 5 μm has occurred between one end (0 mm) and another end (50 mm) of the substrate with a diameter of 2 inches. Therefore, the radius of curvature of the sapphire substrate according to Example 4 is approximately 156 m when it is assumed that the chord length is 50 mm and the camber is 0.002 mm, and the radius of curvature of the sapphire substrate according to Comparative Example 4 is approximately 62 m when it is calculated similarly to Example 4.

That is, it can be seen that, in the sapphire substrate according to Comparative Example 4, the thermal expansion coefficient is different between gallium nitride and sapphire by approximately 2×10⁻⁶ [° C.⁻¹], and the magnitude of thermal shrinkage is different; hence, compressive stress occurs on the gallium nitride side, and deformation occurs such that the gallium nitride side is convex. On the other hand, it can be seen that, in the sapphire substrate according to Example 4, gallium nitride crystal films have been precipitated on both surfaces; thus, compressive stresses cancel each other on both surfaces, and deformation is suppressed.

Therefore, it can be seen that, by the method for producing a gallium nitride crystal according to the present embodiment, the deformation of the substrate on which gallium nitride crystal films are precipitated can be suppressed, and thus dimensional accuracy can be improved during the production of a semiconductor element or the like. In particular, it can be seen that the method for producing a gallium nitride crystal according to the present embodiment is more effective because it is likely that warpage deformation will become larger as the diameter of the substrate on which gallium nitride crystals are precipitated becomes larger.

The preferred embodiment(s) of the present invention has/have been described above with reference to the accompanying drawings, whilst the present invention is not limited to the above examples. A person skilled in the art may find various alterations and modifications within the scope of the appended claims, and it should be understood that they will naturally come under the technical scope of the present invention.

### REFERENCE SIGNS LIST

1 reaction apparatus
2 electric furnace
4 tubular furnace
6 burning zone
8 reaction vessel
100 reaction apparatus
110 melt
111 reaction vessel
112 base
113 electric furnace
114 heater
120 holder
122 lifting shaft
123 sealing material
131 gas introduction port
132 gas exhaust port
140 substrate

1. A method for producing a gallium nitride crystal comprising:
a step of adding at least one or more of a nitride of an alkali metal or an alkaline earth metal and a transition metal to metal gallium and iron nitride and performing heating in a nitrogen atmosphere to at least a reaction temperature at which the metal gallium reacts.

2. The method for producing a gallium nitride crystal according to claim 1,
wherein the nitride of an alkaline earth metal is added to the metal gallium and the iron nitride.

3. The method for producing a gallium nitride crystal according to claim 1,
wherein the nitride of an alkaline earth metal is magnesium nitride.

4. The method for producing a gallium nitride crystal according to claim 1,
wherein the transition metal is any one of manganese, cobalt, and chromium.

5. The method for producing a gallium nitride crystal according to claim 1,
wherein the iron nitride contains at least one or more of tetrairon mononitride, triiron mononitride, and diiron mononitride.

6. The method for producing a gallium nitride crystal according to claim 1,
wherein the reaction temperature is more than or equal to 550° C. and less than or equal to 1000° C.

7. The method for producing a gallium nitride crystal according to claim 1,
wherein the gallium nitride crystal is formed on a substrate by a liquid phase epitaxy method.

8. The method for producing a gallium nitride crystal according to claim 7,
wherein the substrate is a sapphire substrate.

9. The method for producing a gallium nitride crystal according to claim 7,
wherein gallium nitride crystals are formed on both surfaces of the substrate simultaneously.
